(19) United States
(12) Patent Application Publication
(10) Pub. No.: US 2024/0234466 A1
(43) Pub. Date: Jul. 11, 2024

(54) IMAGE SENSING DEVICE AND METHOD FOR MANUFACTURING THE SAME

(71) Applicant: SK hynix Inc., Icheon-si (KR)

(72) Inventor: Han Seung LEE, Icheon-si (KR)

(21) Appl. No.: 18/346,043

(22) Filed: Jun. 30, 2023

(30) Foreign Application Priority Data
Jan. 11, 2023 (KR) 10-2023-0003903

(51) Int. Cl. H01L 27/146

(52) U.S. Cl. CPC H01L 27/1463; H01L 27/14683

(57) ABSTRACT

Disclosed are image sensing devices including a pixel array that includes a plurality of unit pixels arranged therein, and an isolation area between the unit pixels, wherein the isolation area includes a first isolation layer formed to have a first depth, a second isolation layer formed to have a second depth, and a third isolation layer disposed between the first isolation layer and the second isolation layer and formed to have a third depth, and the third depth is greater than the first depth and the second depth.

### PRIORITY CLAIM AND CROSS REFERENCE TO RELATED APPLICATION

This patent document claims the priority and benefits of Korean Patent Application No. 10-2023-0003903, filed on Jan. 11, 2023, which is incorporated by reference in its entirety as part of the disclosure of this patent document.

### TECHNICAL FIELD

Various embodiments of the disclosed technology relate to an image sensing device and a method of manufacturing the image sensing device.

### BACKGROUND

An image sensing device refers to a semiconductor device that captures and converts an optical image to electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device capable of reducing or minimizing crosstalk between pixels and blocking a current path between a pixel transistor and a pixel well, and a manufacturing method thereof.

In an embodiment, an image sensing device includes a pixel array including a plurality of unit pixels arranged therein, and an isolation area formed between the unit pixels, wherein the isolation area may include a first isolation layer formed to have a first depth, a second isolation layer formed to have a second depth, and a third isolation layer disposed between the first isolation layer and the second isolation layer and formed to have a third depth, and the third depth may be greater than the first depth and the second depth.

The isolation area may include a control node region and a pixel transistor well region, and the first isolation layer may be formed on the control node region.

The second isolation layer may be formed on the pixel transistor well region.

The second depth may be greater than the first depth.

The third depth is a depth formed to provide full isolation.

The control node region may be formed in a corner region in a first diagonal direction of a unit pixel of the plurality of unit pixels.

The pixel transistor well region may be formed in a corner region of the unit pixel in a second diagonal direction of the unit pixel perpendicular to the first diagonal direction.

In an embodiment, an image sensing device includes a pixel array including a plurality of pixels arranged therein, an isolation area formed between the unit pixels, wherein the isolation area includes a control node region formed in a corner region in a first diagonal direction, of a unit pixel of the plurality of unit pixels, a pixel transistor well region formed in a corner region of the unit pixel in a second diagonal direction perpendicular to the first diagonal, a first isolation layer formed on the control node region, a second isolation layer formed on the pixel transistor well region, and a third isolation layer formed between the first isolation layer and the second isolation layer, and at least one of the first isolation layer, the second isolation layer, and the third isolation layer has a different depth from other isolation layers.

The depth of the third isolation layer may be greater than the depths of the first isolation layer and the second isolation layer.

The depth of the second isolation layer may be greater than the depth of the first isolation layer.

The depth of the second isolation layer may be equal to the depth of the first isolation layer.

In an embodiment, a method of manufacturing an image sensing device includes forming a first isolation layer in a corner region of a unit pixel in a first diagonal direction of the unit pixel, forming a third isolation layer in a direction in which the first isolation layer extends, forming a second isolation layer in a corner region of the unit pixel in a second diagonal direction perpendicular to the first diagonal direction, and forming an additional depth of the third isolation layer such that the third isolation layer has a third depth.

The forming the first isolation layer may include etching the first isolation layer to a first depth.

The forming the third isolation layer may include etching the third isolation layer to a depth that is equal to the first depth.

The forming the second isolation layer may include etching the second isolation layer to a second depth that is equal to the first depth.

The forming the second isolation layer may include etching the second isolation layer to a second depth that is greater than the first depth.

The forming the additional depth of the third isolation layer may include forming the additional depth of the third isolation layer such that the third depth of the third isolation layer is greater than the first depth and the second depth.

### BRIEF DESCRIPTION OF THE DRAWINGS

FIG. 1 is a block diagram of an image sensing device based on an embodiment.

FIG. 2 is a plan view of a photodiode area of an image sensing device based on an embodiment.

FIGS. 3 and 4 are cross-sectional views of an optic structure of an image sensing device based on some embodiments.

FIG. 5 is a flowchart of a method of manufacturing an image sensing device based on an embodiment.

FIGS. 6 to 10 show a method of manufacturing an image sensing device based on an embodiment.

### DETAILED DESCRIPTION

Features, and certain advantages in connection with specific implementations of the disclosed technology disclosed in this patent document are described by example with reference to the accompanying drawings so.

In a diagonal arrangement of an image sensor pixel array in a time-of-flight (ToF) sensor, pixel wells, control nodes, and detection nodes may hinder isolation structures from properly isolating adjacent image sensor pixels from each other.

In addition, a doping process that is performed to form a deep trench isolation (DTI) structure may cause physical damage to the image sensor pixel array, creating a dark current source that can deteriorate the characteristics of the image sensor pixel array.

In order to address such issues, the disclosed technology can be implemented in some embodiments to provide an image sensing device having isolation structures with different depths for pixels area, thereby reducing or minimizing the optical crosstalk in a pixel array including a plurality of image sensing pixels.

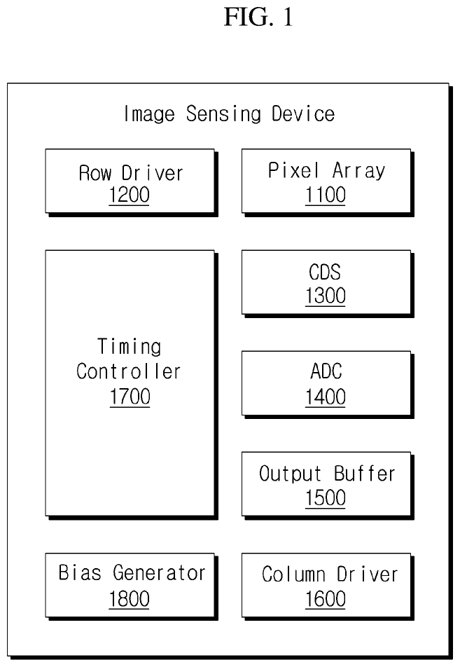

FIG. 1 is a block diagram of an image sensing device based on an embodiment.

Referring to FIG. 1, an image sensing device according to an embodiment may include a pixel array 1100, a row driver 1200, a correlated double sampler (CDS) 1300, and an analog-to-digital converter (ADC) 1400, an output buffer 1500, a column driver 1600, a timing controller 1700, and a bias generator 1800. Here, the components of the image sensing device are merely exemplary, and at least some components may be added or omitted as needed.

The pixel array 1100 may include a plurality of pixels arranged in a plurality of rows and a plurality of columns. In an embodiment, the plurality of pixels may be arranged in a two-dimensional pixel array including rows and columns. In another embodiment, a plurality of unit image pixels may be arranged in a three-dimensional pixel array. A plurality of pixels may convert an optical signal into an electrical signal on a pixel basis or on a pixel group basis, and pixels in a pixel group may share at least a specific internal circuit. The pixel array 1100 may receive a driving signal including a row selection signal, a pixel reset signal, a transmission signal and others from the row driver 1200, and a corresponding pixel of the pixel array 1100 may be enabled by the driving signal to perform operations corresponding to the row selection signal, the pixel reset signal and the transmission signal.

The row driver 1200 may enable the pixel array 1100 to perform specific operations on pixels included in a corresponding row based on commands and control signals supplied by the timing controller 1700. In an embodiment, the row driver 1200 may select at least one pixel arranged in at least one row of the pixel array 1100. The row driver 1200 may generate a row selection signal to select at least one row out of a plurality of rows. The row driver 1200 may sequentially enable pixel reset signals and transmission signals for pixels corresponding to at least one row selected. Accordingly, analog reference signals and image signals generated by the pixels of the selected row may be sequentially transmitted to the correlate doubled sampler 1300. Here, the reference signal may be an electrical signal that is provided to the correlated double sampler 1300 when a sensing node (e.g., floating diffusion node) for the pixel is reset, and the image signal may be an electrical signal that is provided to the correlated double sampler 1300 when photoelectric charge generated by the pixel is accumulated in the sensing node. The reference signal representing reset noise that is inherent for the pixel and the image signal representing the intensity of incident light may be collectively referred to as a pixel signal.

CMOS image sensors may use correlate double sampling to eliminate undesired offset values of pixels, such as fixed pattern noise, by sampling the pixel signal twice and removing a difference between two samples. For example, the correlate double sampling may remove an undesired offset value by comparing pixel output voltages obtained before and after the photoelectric charge generated by the incident light is accumulated in the sensing node, so that the pixel output voltage based only on the incident light may be measured. In an embodiment, the correlated double sampler 1300 may sequentially sample and hold the reference signal and the image signal provided to each of a plurality of column lines from the pixel array 1100. That is, the correlated double sampler 1300 may sample and hold the level of the reference signal and the level of the image signal corresponding to each of the columns of the pixel array 1100.

The correlated double sampler 1300 may transfer the reference signal and the image signal of each column to the ADC 1400 as correlate double sampling signals based on a control signal from the timing controller 1700.

The ADC 1400 may convert the correlated double sampling signal for each column output from the correlated double sampler 1300 into a digital signal and output the digital signal. In an embodiment, the ADC 1400 may be implemented with a ramp-compare type ADC. The ramp-compare type ADC may include a comparison circuit that compares a ramp signal that rises or falls with time and an analog pixel signal, and a counter that performs a counting operation. In an example, the counter may perform the counting operation until the ramp signal matches an analog pixel signal. In another example, the counter may count the number of crossing points of the ramp signal and the analog pixel signal. In an embodiment, the ADC 1400 may convert a correlated double sampling signal generated by the correlated double sampler 1300 for each column into a digital signal and output the digital signal.

The ADC 1400 may include a plurality of column counters respectively corresponding to the columns of the pixel array 1100. Each column of the pixel array 1100 is connected to each column counter, and image data may be generated by converting a correlated double sampling signal corresponding to each column into a digital signal using the column counters. In another embodiment, the ADC 1400 may include one global counter and convert a correlated double sampling signal corresponding to each column into a digital signal using a global code provided by the global counter.

The output buffer 1500 may temporarily hold and output image data per each column provided from the ADC 1400. The output buffer 1500 may temporarily store image data output from the ADC 1400 based on a control signal from the timing controller 1700. The output buffer 1500 may operate as an interface that compensates for a difference in transmission (or processing) speed between the image sensing device and other devices connected to the image sensing device.

The column driver 1600 may select a column of the output buffer 1500 based on a control signal from the timing controller 1700 and perform control operations such that pieces of image data temporarily stored in the selected columns of the output buffer 1500 are sequentially output. In an embodiment, the column driver 1600 may receive an address signal from the timing controller 1700, and the column driver 1600 may select a column of the output buffer 1500 by generating a column selection signal based on the address signal to perform control such that the image data is output from the selected column of the output buffer 1500 to the outside.

The timing controller 1700 may control at least one of the row driver 1200, the correlated double sampler 1300, the ADC 1400, the output buffer 1500, the column driver 1600, and the bias generator 1800.

The timing controller 1700 may provide a clock signal required for operation of each component of the image sensing device, a control signal for timing control, address signals for selecting a row or column, a signal for controlling a level of a bias voltage applied to the pixel array 1100, or others like to at least one of the row driver 1200, the correlated double sampler 1300, the ADC 1400, the output buffer 1500, the column driver 1600 and the bias generator 1800. In an embodiment, the timing controller 1700 may include a logic control circuit, a phase lock loop (PLL) circuit, a timing control circuit, and a communication interface circuit, and others.

The bias generator 1800 may generate a bias voltage for suppressing dark current generated in pixels of the pixel array 1100 and supply the generated bias voltage to the pixel array 1100.

The bias voltage may be determined in a wafer probe test process for the image sensing device and stored in a One-Time Programmable (OTP) memory. For example, the bias voltage may be experimentally determined as a value capable of maximizing a dark current suppression effect while minimizing unnecessary power consumption without deteriorating performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In an embodiment, the bias voltage may include a plurality of values.

For example, a plurality of values may respectively correspond to a plurality of operation modes of the image sensing device. Dark current generated at low light levels may be different from dark current generated at high light levels, and a bias voltage provided by the bias generator 1800 to effectively suppress dark current in each environment may vary depending on modes.

Alternatively, a plurality of values may respectively correspond to a plurality of regions of the pixel array 1100. The generated dark current may be different according to the positions of pixels on the pixel array 1100, and the bias voltage provided by the bias generator 1800 to effectively suppress the dark current regardless of the position of the pixel may vary depending on the regions of the pixel array 1100.

The bias voltage may be a negative voltage having a negative sign, but the scope of the disclosed technology is not limited thereto.

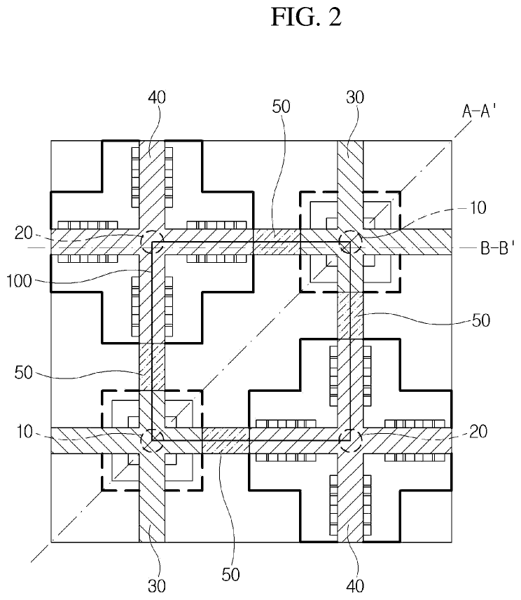

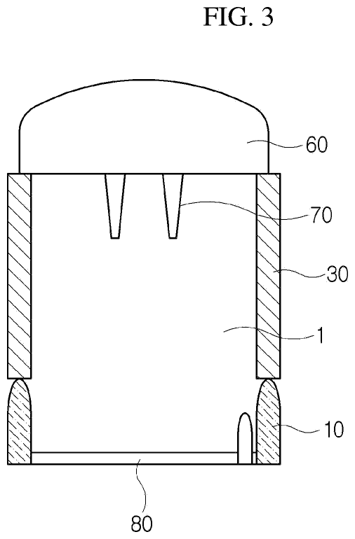

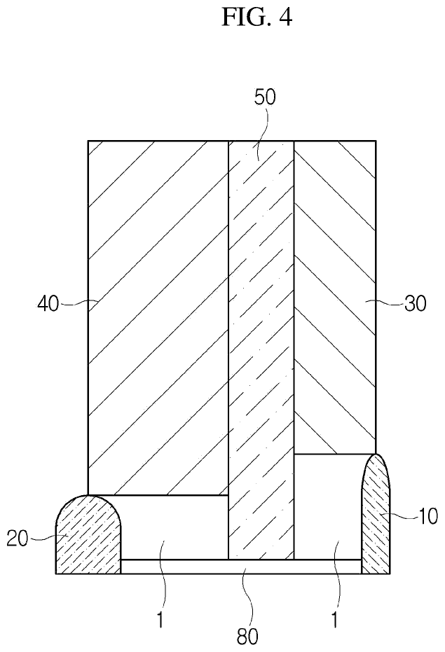

FIG. 2 is a plan view of a photodiode area of an image sensing device based on an embodiment. FIGS. 3 and 4 are cross-sectional views of an optic structure of an image sensing device based on some embodiments.

Referring to FIG. 2, an image sensing device according to an embodiment may include a pixel array that includes a plurality of unit pixels 100 arranged in rows and columns in the pixel array and arranged in a diagonal structure. In the illustrated example in FIG. 2, the unit pixels 100 are shaped as a square or a rectangle and placed in an array with orthogonal rows and columns. Each unit pixel has 4 vertices at the 4 corners of the unit pixel and, a line connecting two opposing vertices in each unit pixel defines a diagonal direction for the unit pixel in either a square or rectangle shape, such as the diagonal line A-A′ connecting two opposing vertices on the left-lower corner and the right-upper corner, and another diagonal line B-B′ connecting two other opposing vertices on the left-upper corner and the right-lower corner.

In some implementations, an isolation area may be formed between adjacent unit pixels 100. As shown in FIG. 2, in some implementations, a unit pixel 100 is surrounded by 8 adjacent unit pixels (FIG. 2 shows part of the 8 adjacent unit pixels) and the isolation area is arranged along boundaries between adjacent unit pixels 100.

In some implementations, the isolation area may include a plurality of isolation layers formed therein. As an example, the plurality of isolation layers may include a first isolation layer 30 formed in corner regions on both sides of the unit pixel 100 in a first diagonal direction (e.g., direction of A-A′ in FIG. 2) in the pixel array.

In some implementations, the first isolation layer 30 may have a deep trench isolation (DTI) structure, and may include a silicon oxide material as an insulating material.

In an embodiment, the plurality of isolation layers in the isolation area may include a second isolation layer 40 formed in corner regions on both sides of the unit pixel 100 in a second diagonal direction B-B′ (e.g., a direction that is perpendicular to or different from the first diagonal direction A-A′) in the pixel array. In some implementations, the unit pixels 100 are arranged in rows and columns in the pixel array as shown in FIG. 2, and the first and second diagonal directions indicate diagonal directions of the pixel array.

In an embodiment, the second isolation layer 40 may have a DTI (Deep Trench Isolation) structure, and include a silicon oxide material as an insulating material.

In an embodiment, the plurality of isolation layers in the isolation area may include a third isolation layer 50 formed between the first isolation layer 30 and the second isolation layer 40.

In an embodiment, the third isolation layer 50 may have a full shallow trench isolation (FTI) structure, and include a silicon oxide material as an insulating material.

Referring to FIG. 3, a first isolation layer 30, a control node region 10, and a trench guide 70 can be formed in a substrate 1, and a lens portion 60 is disposed over the substrate 1. In an embodiment, control node regions 10 may be formed at corner regions on both sides of the unit pixel 100 in the first diagonal direction (e.g., the direction of A-A′) in the pixel array. In some implementations, the control node regions 10 includes a control node (P+/P−). In some implementations, the control node regions 10 may be used to control operations of the unit pixel 100.

In an embodiment, the first isolation layer 30 may be formed on the control node region 10.

In an embodiment, the lens portion 60 may be formed on the first isolation layer 30.

In an embodiment, the trench guide 70 may be formed under the lens portion 60.

In an embodiment, pixel transistor well regions 20 may be formed in the corner regions on both sides in the second diagonal direction (e.g., the direction perpendicular to or different from the first diagonal direction) of the unit pixel 100. In an implementation, the pixel transistor well regions 20 may include an n-type well diffused on a p-type substrate. In another implementation, the pixel transistor well regions 20 may include an p-type well diffused on a n-type substrate.

In an embodiment, the second isolation layer 40 may be formed on the pixel transistor well region 20.

Referring to FIG. 4, in an embodiment, the first isolation layer 30 may be formed to have a first depth in the substrate 1. In an embodiment, the first depth may be 5 μm or less.

In an embodiment, the second isolation layer 40 may be formed to have a second depth in the substrate 1. The second depth may be equal to or greater than the first depth. In an embodiment, the second depth may be 6 μm or less.

In an embodiment, the third isolation layer 50 may be formed to have a third depth in the substrate 1. The third depth is a depth capable of fully isolating adjacent unit pixels, and may be greater than the first depth and the second depth. In an embodiment, the third depth may be 7 μm or less. In an embodiment, the third isolation layer 50 may have a depth that can reach an upper portion of an oxide stopper 80.

The first depth, the second depth, and the third depth may have various depth values depending on the thickness of silicon (Si) of a substrate 1, the arrangement of gates in unit pixels, the arrangement of control nodes and detection nodes, or doping regions.

In a case where a deep trench isolation (DTI) structure is formed between unit pixels that include gates of indirect time of flight (ToF) sensor and one control node shared by four detection nodes, physical damage may be caused to the doping regions, creating a dark current source that can deteriorate the characteristics of the image sensor pixel array.

Such an isolation structure may reduce an optical crosstalk between pixels and block a current path between the control node region 10 and the pixel transistor well region 20, but may cause a dark current. In order to reduce the optical crosstalk and block the current path without causing the dark current, the disclosed technology can be implemented in some embodiments to provide an isolation structure that includes an isolation layer having a depth to the extent that can reduce the optical crosstalk and block the current path without causing the dark current, by avoiding forming the isolation layer in regions that can cause the dark current, based on a doping profile of the isolation structure and adjacent material layers. In this way, the isolation structure implemented based on some embodiments can physically block a current path between the control node region 10 and the pixel transistor well region 20 and reduce or minimize inter-pixel optical crosstalk while avoiding causing the dark current.

In addition, the disclosed technology can be implemented in some embodiments to control optical crosstalk between pixels by separating the nodes between pixels through the first isolation layer 30 and the third isolation layer 50. In this way, it is possible to reduce power consumption by physically blocking a current leakage path between the control node region 10 and the pixel transistor well region 20 through the second isolation layer 40 and the third isolation layer 50.

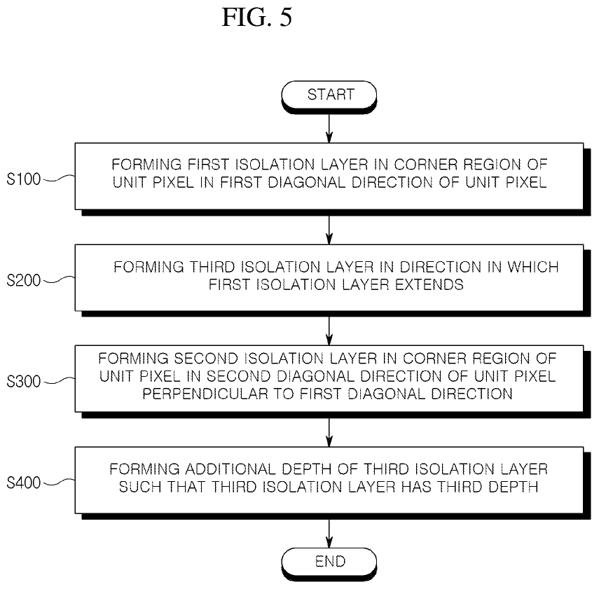

FIG. 5 is a flowchart of a method of manufacturing an image sensing device based on an embodiment.

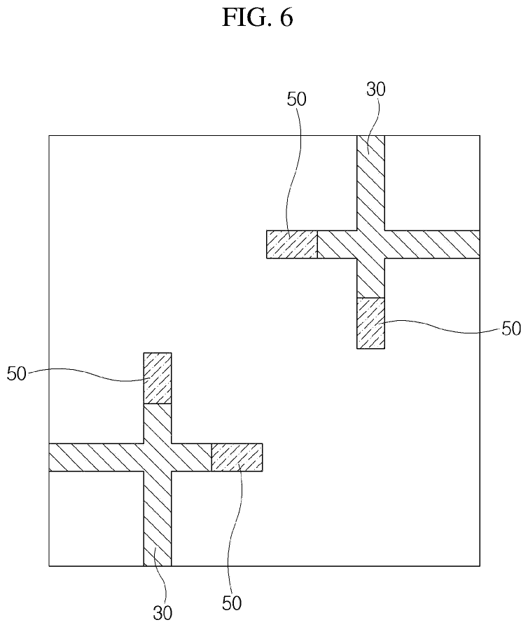

FIGS. 6 to 10 show a method of manufacturing an image sensing device based on an embodiment.

Referring to FIG. 5, a method of manufacturing an image sensing device based on an embodiment may include forming a first isolation layer 30 in a corner region of a unit pixel 100 in a first diagonal direction (S100), forming a third isolation layer 50 in a direction in which the first isolation layer 30 extends (S200); forming a second isolation layer 40 in a corner region of the unit pixel 100 in a second diagonal direction different from or perpendicular to the first diagonal direction (S300), and additionally forming an additional depth of the third isolation layer 50 (S400).

Referring to FIG. 6, before forming the first isolation layer 30 (S100), a photoresist pattern for a DTI mask may be formed such that regions in which the first isolation layer 30 and the third isolation layer 50 are to be formed are open.

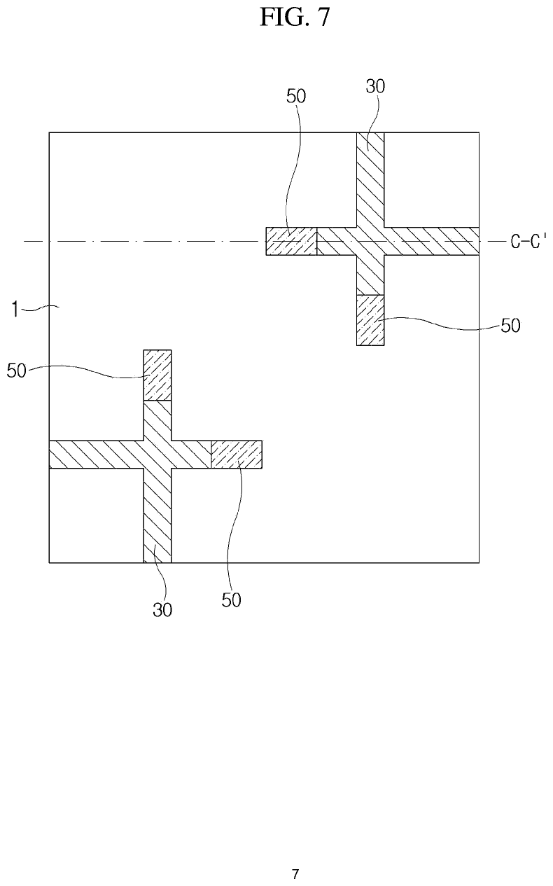

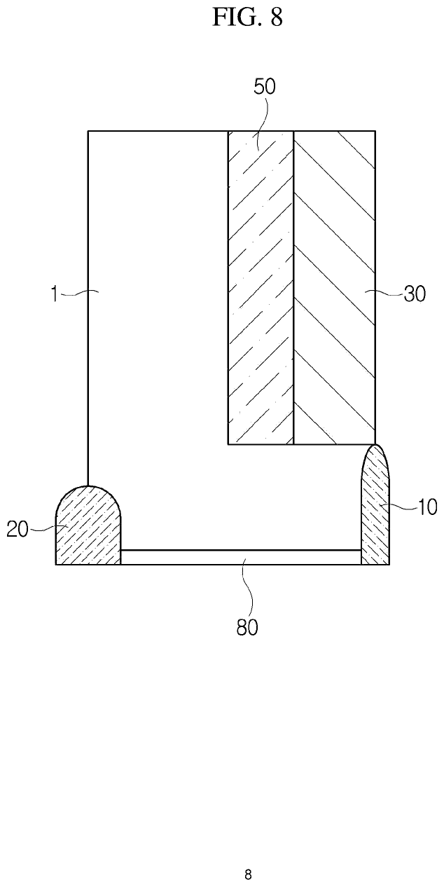

Referring to FIGS. 7 and 8, the forming of the first isolation layer 30 (S100) may include forming the first isolation layer 30 through a process of performing an etching process to a first depth and depositing an insulating material. In an embodiment, the first depth may be 5 μm or less.

In some implementations, the forming of the third isolation layer 50 (S200) may include forming a partial region of the third isolation layer 50 through a process of etching the third isolation layer 50 to the same first depth as the first isolation layer 30. In this case, the depth of the third isolation layer 50 may be 5 μm or less, as an example.

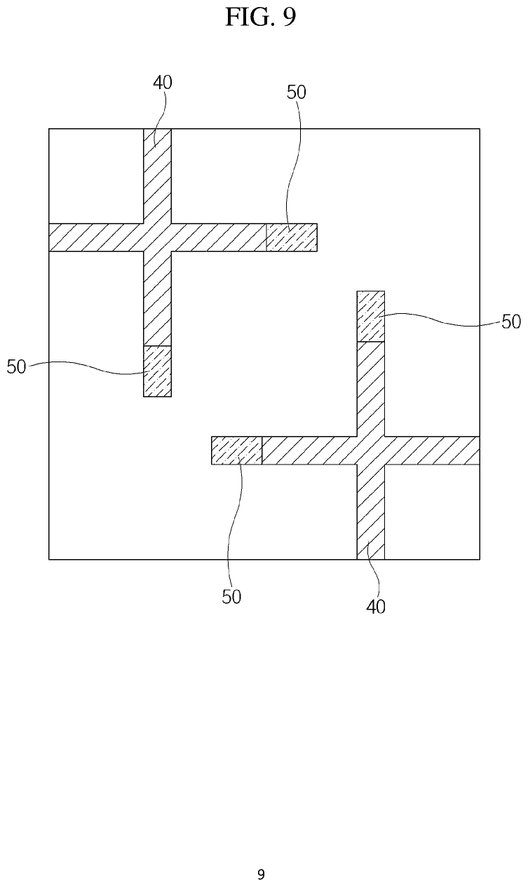

Referring to FIG. 9, after forming the third isolation layer 50 (S200), a photoresist pattern for the DTI mask may be formed such that a region in which the second isolation layer 40 are to be formed and a region in which the third isolation layer 50 are to be formed are open.

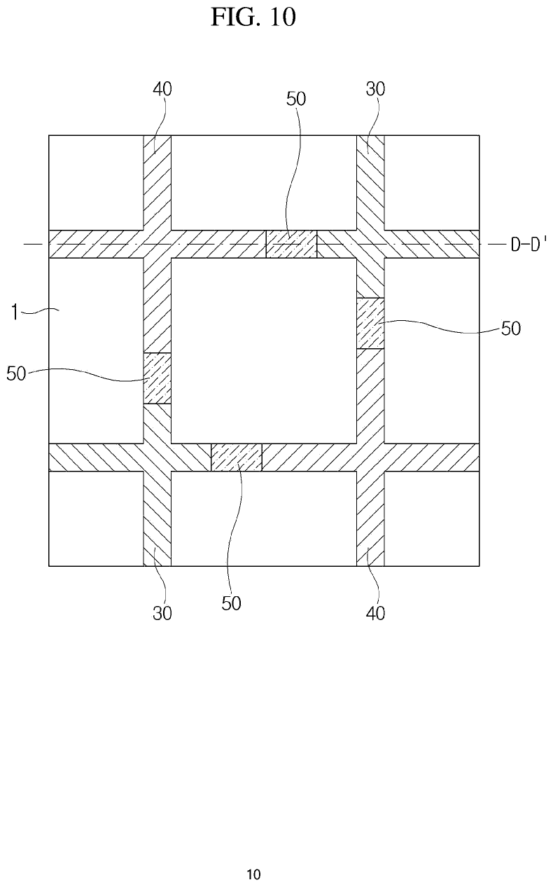

Referring to FIG. 10, the forming of the second isolation layer 40 (S300) may include forming the second isolation layer 40 through a process of performing an etching process to the second depth that is equal to or greater than the first depth and depositing an insulating material. In an embodiment, the second depth may be 6 μm or less.

In some implementations, the additionally forming of the depth of the third isolation layer 50 (S400) may include forming the entire area of the third isolation layer 50 through a process of etching the third isolation layer 50 to a third depth that is greater than the first depth and the second depth and depositing an insulating material. In this case, the depth of the third isolation layer 50 additionally formed may be 7 μm or less.

As discussed above, the disclosed technology can be implemented in some embodiments to control inter-pixel optical crosstalk by separating nodes between pixels from each other through the first isolation layer 30 and the third isolation layer 50.

As discussed above, the disclosed technology can be implemented in some embodiments to reduce power consumption by physically blocking a current path between the control node region 10 and the pixel transistor well region 20 through the second isolation layer 40 and the third isolation layer 50.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. An image sensing device comprising:
a pixel array including a plurality of unit pixels arranged therein; and
an isolation area formed between the unit pixels,
wherein the isolation area comprises
a first isolation layer formed to have a first depth;
a second isolation layer formed to have a second depth; and
a third isolation layer disposed between the first isolation layer and the second isolation layer and formed to have a third depth, and
wherein the third depth is greater than the first depth and the second depth.

2. The image sensing device of claim 1, wherein the isolation area further includes a control node region and a pixel transistor well region, and wherein the first isolation layer is formed on the control node region.

3. The image sensing device of claim 2, wherein the second isolation layer is formed on the pixel transistor well region.

4. The image sensing device of claim 1, wherein the second depth is greater than the first depth.

5. The image sensing device of claim 1, wherein the third depth is a depth formed to provide full isolation.

6. The image sensing device of claim 2, wherein the control node region is formed in a corner region in a first diagonal direction of a unit pixel of the plurality of unit pixels.

7. The image sensing device of claim 6, wherein the pixel transistor well region is formed in a corner region of the unit pixel in a second diagonal direction perpendicular to the first diagonal direction.

8. An image sensing device comprising:
a pixel array including a plurality of unit pixels arranged therein;
an isolation area formed between the unit pixels,
wherein the isolation area comprises:
a control node region formed in a corner region in a first diagonal direction, of a unit pixel of the plurality of unit pixels;
a pixel transistor well region formed in a corner region of the unit pixel in a second diagonal direction perpendicular to the first diagonal direction;
a first isolation layer formed on the control node region;
a second isolation layer formed on the pixel transistor well region; and
a third isolation layer formed between the first isolation layer and the second isolation layer,
wherein at least one of the first isolation layer, the second isolation layer, and the third isolation layer has a different depth from other isolation layers.

9. The image sensing device of claim 8, wherein the depth of the third isolation layer is greater than the depths of the first isolation layer and the second isolation layer.

10. The image sensing device of claim 8, wherein the depth of the second isolation layer is greater than the depth of the first isolation layer.

11. The image sensing device of claim 8, wherein the depth of the second isolation layer is equal to the depth of the first isolation layer.

12. A method of manufacturing an image sensing device, comprising:
forming a first isolation layer in a corner region of a unit pixel in a first diagonal direction of the unit pixel;
forming a third isolation layer in a direction in which the first isolation layer extends;
forming a second isolation layer in a corner region of the unit pixel in a second diagonal direction of the unit pixel perpendicular to the first diagonal direction; and
forming an additional depth of the third isolation layer such that the third isolation layer has a third depth.

13. The method of claim 12, wherein the forming the first isolation layer comprises etching the first isolation layer to a first depth.

14. The method of claim 13, wherein the forming the third isolation layer comprises etching the third isolation layer to a depth that is equal to the first depth.

15. The method of claim 14, wherein the forming the second isolation layer comprises etching the second isolation layer to a second depth that is equal to the first depth.

16. The method of claim 14, wherein the forming the second isolation layer comprises etching the second isolation layer to a second depth that is greater than the first depth.

17. The method of claim 15, wherein the forming the additional depth of the third isolation layer comprises forming the additional depth of the third isolation layer such that the third depth of the third isolation layer is greater than the first depth and the second depth.

18. The method of claim 16, wherein the forming the additional depth of the third isolation layer comprises forming the additional depth of the third isolation layer such that the third depth of the third isolation layer is greater than the first depth and the second depth.
